(19) United States
(12) Patent Application Publication
(10) Pub. No.: US 2023/0005961 A1
(43) Pub. Date: Jan. 5, 2023

(54) DISPLAY DEVICE AND MANUFACTURING METHOD OF THE SAME

(71) Applicant: Samsung Display Co., LTD., Yongin-si (KR)

(72) Inventors: Dae Hwan JANG, Yongin-si (KR); Seok Hyun NAM, Yongin-si (KR); Jin Ho CHO, Yongin-si (KR)

(73) Assignee: Samsung Display Co., LTD., Yongin-si (KR)

(21) Appl. No.: 17/692,371

(22) Filed: Mar. 11, 2022

(30) Foreign Application Priority Data
Jun. 30, 2021 (KR) 10-2021-0086006

(51) Int. Cl. H01L 27/12; H01L 25/16; H01L 23/00

(52) U.S. Cl. CPC H01L 27/124; H01L 25/167; H01L 24/05; H01L 24/32; H01L 24/83; H01L 2224/05022; H01L 2224/05026; H01L 2224/05166; H01L 2224/05558; H01L 2224/05565; H01L 2224/05567; H01L 2224/05573; H01L 2224/05647; H01L 2224/32013; H01L 2224/32111; H01L 2224/32238; H01L 2224/3224; H01L 2224/83365; H01L 2224/83801; H01L 2224/8313

(57) ABSTRACT

A display device includes a first base layer including a first opening; a first barrier layer located on a surface of the first base layer, and including a second opening; and a pad electrode located on the first barrier layer and overlapping the second opening in a plan view. At least one first groove is formed at a surface of the first barrier layer, a second groove is formed at a surface of the pad electrode, and the first opening exposes the at least one first groove and the second groove.

### CROSS-REFERENCE TO RELATED APPLICATION(S)

The application claims priority to and the benefit of Korean patent application 10-2021-0086006 under 35 U.S.C. § 119, filed on Jun. 30, 2021, in the Korean Intellectual Property Office (KIPO), the entire contents of which are incorporated herein by reference.

### BACKGROUND

### 1. Technical Field

The disclosure generally relates to a display device and a manufacturing method of the same.

### 2. Related Art

As interest in information displays and demand for portable information media increase, research and commercialization has focused on display devices.

### SUMMARY

Embodiments provide a display device and a manufacturing method of the same, in which a short circuit of the display device can be prevented.

In accordance with an aspect of the disclosure, there is provided a display device including a first base layer including a first opening; a first barrier layer located on a surface of the first base layer, and including a second opening; and a pad electrode located on the first barrier layer, and overlapping the second opening in a plan view. At least one first groove is formed at a surface of the first barrier layer, and a second groove is formed at a surface of the pad electrode, and the first opening exposes the at least one first groove and the second groove.

The pad electrode and a chip on film may be electrically connected to each other through the first opening.

The pad electrode and the chip on film may be electrically connected to each other through a connection ball.

The connection ball may be located in the second groove formed in the pad electrode.

The pad electrode may include a first layer and a second layer. The first layer may include titanium, and the second layer may include copper.

The second groove may be formed at a lower surface of the second layer.

The display device may further include a second barrier layer overlapping an upper surface of the first barrier layer and an upper surface of the pad electrode in a plan view; a second base layer located on the second barrier layer; and a pixel circuit layer located on the second base layer. The pixel circuit layer may include a data line.

The second base layer may include an opening filled with a conductive material. The data line may be electrically connected to the pad electrode through the conductive material.

In accordance with another aspect of the disclosure, there is provided a method of manufacturing a display device, the method including forming at least one metal part on a surface of a base layer; forming a first barrier layer on the base layer and the at least one metal part; forming a pad electrode on the first barrier layer; forming a second barrier layer on the first barrier layer and the pad electrode; and forming a first opening in the base layer, forming a first groove at a lower surface of the first barrier layer by removing the at least one metal part, and forming a second groove at a lower surface of the pad electrode by partially removing the pad electrode.

The forming of the first groove and the forming of the second groove may include using an atmospheric pressure plasma process to form the first and second grooves.

The forming of the first barrier layer may include depositing the barrier layer on the base layer and the at least one metal part, and forming a second opening in the first barrier layer.

The forming of the pad electrode may include depositing a pad electrode material on the first barrier layer, and forming the pad electrode such that a portion of the pad electrode overlaps the second opening in a plan view.

A second groove may be formed at the lower surface of the pad electrode disposed in the second opening.

A connection ball electrically connecting a chip on film and the pad electrode to each other may be provided to correspond to the second groove.

In accordance with still another aspect of the disclosure, there is provided a display device including at least one display panel including a first base layer including a first opening; a first barrier layer located on a surface of the first base layer, the first barrier layer including a second opening; and a pad electrode located on the first barrier layer and overlapping the second opening in a plan view. At least one first groove is formed at a surface of the first barrier layer, and a second groove is formed at a surface of the pad electrode, and the first opening exposes the at least one first groove and the second groove.

In the first opening, the pad electrode and a chip on film may be electrically connected to each other through a connection ball.

The pad electrode may include a first layer and a second layer. The first layer may include titanium, and the second layer may include copper.

The second groove may be formed at a lower surface of the second layer.

The display device may further include a second barrier layer overlapping an upper surface of the first barrier layer and an upper surface of the pad electrode in a plan view; a second base layer located on the second barrier layer; and a pixel circuit layer located on the second base layer. The pixel circuit layer may include a data line.

The second base layer may include an opening filled with a conductive material. The data line may be electrically connected to the pad electrode through the conductive material.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment.

FIG. 2 is a schematic plan view illustrating one display device in accordance with an embodiment.

FIG. 3 is a schematic diagram of an equivalent circuit illustrating a pixel of a display device in accordance with an embodiment.

FIG. 4 is a schematic cross-sectional view mainly illustrating a pixel circuit layer and a display element layer of a pixel of a display device in accordance with an embodiment.

FIG. 5 is a schematic cross-sectional view mainly illustrating a pixel circuit layer, a display element layer, a light conversion layer, and the like of a display device in accordance with an embodiment.

FIG. 6 is a schematic cross-sectional view mainly illustrating a pixel circuit layer, a display element layer, a light conversion layer, and the like of a display device in accordance with an embodiment.

FIG. 7 is a schematic cross-sectional view illustrating a display device in accordance with an embodiment.

FIGS. 8 to 10 are schematic cross-sectional views sequentially illustrating a manufacturing method of the display device shown in FIG. 7.

FIG. 11 is a schematic cross-sectional view illustrating a state in which a chip on film is attached to a display device in accordance with an embodiment.

FIG. 12 is a schematic rear view illustrating a state in which a first opening is formed on a base layer of a display device in accordance with an embodiment.

FIG. 13 is a schematic rear view illustrating a state in which a chip on film is attached to a display device in accordance with an embodiment.

### DETAILED DESCRIPTION OF THE EMBODIMENTS

The disclosure may apply various changes and different shape, therefore only illustrate in detail with particular examples. However, the examples do not limit to certain shapes but apply to all the change and equivalent material and replacement. The drawings included are illustrated a fashion where the figures are expanded for the better understanding.

It will be understood that, although the terms “first”, “second”, and the like may be used herein to describe various elements, these elements should not be limited by these terms. These terms are only used to distinguish one element from another element. Thus, a “first” element discussed below could also be termed a “second” element without departing from the teachings. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be understood that the terms “contact,” “connected to,” and “coupled to” may include a physical and/or electrical contact, connection, or coupling, and vice versa.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, an

Hereinafter, embodiments will be described in detail with reference to the accompanying drawings.

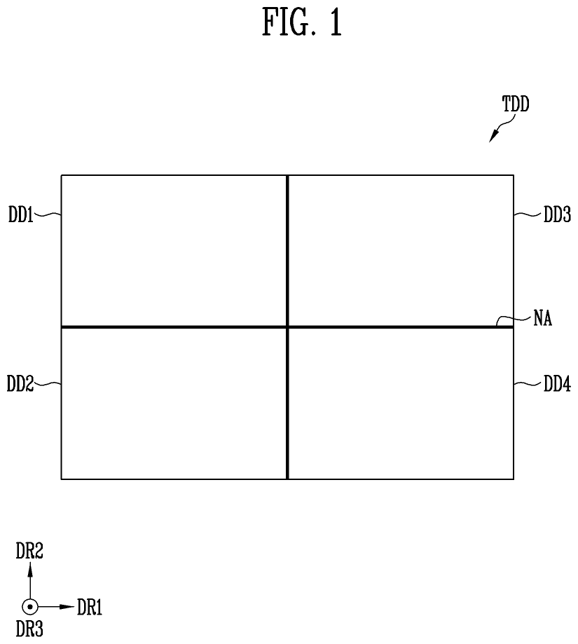

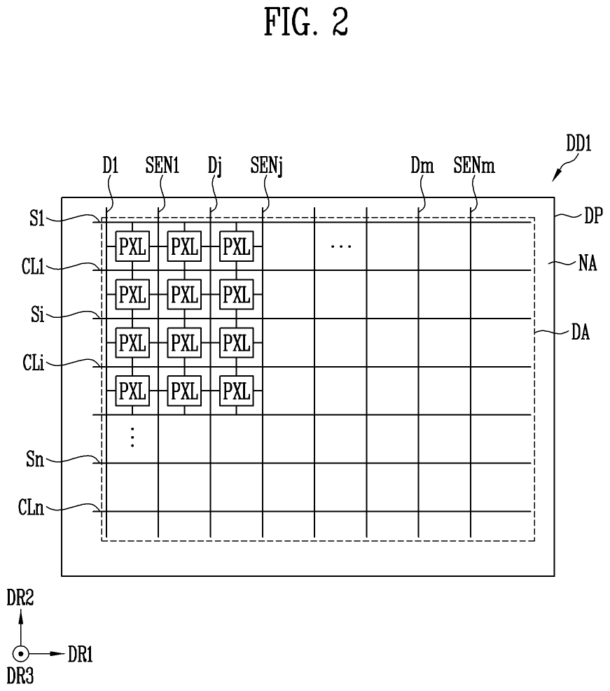

FIG. 1 is a schematic plan view illustrating a display device in accordance with an embodiment. FIG. 2 is a schematic plan view illustrating a display device in accordance with an embodiment.

Referring to FIG. 1, the display device may be a multi-screen display device TDD including display panels.

The multi-screen display device TDD (also referred to as a tiled display) may include display devices DD1, DD2, DD3, and DD4 arranged in a matrix form in a first direction DR1 and a second direction DR2.

The display devices DD1, DD2, DD3, and DD4 may respectively display individual images, or divisionally display an image. The display devices DD1, DD2, DD3, and DD4 may include display panels having the same kind, structure, size or type, but the disclosure is not limited thereto.

The display devices DD1, DD2, DD3, and DD4 may be physically combined with each other by a housing (not shown) which may be located on the bottom of the display devices DD1, DD2, DD3, and DD4, to constitute a multi-screen display device TDD.

The display devices DD1, DD2, DD3, and DD4 may be implemented in various shapes. Although FIG. 1 illustrates that the display devices DD1, DD2, DD3, and DD4 have a rectangular plate shape, the disclosure is not limited thereto, and each of the display devices DD1, DD2, DD3, and DD4 may have a shape such as a circular shape or an elliptical shape.

A display device DD1 among the display devices DD1, DD2, DD3, and DD4 will be described with reference to FIG. 2.

The display device DD1 includes a display area DA and a non-display area NA which are implemented or provided on a display panel DP. The display area DA is an area including pixels PXL, thereby displaying an image, and the non-display area NA is an area that is the display area DA, thereby not displaying an image. The non-display area NA may be a bezel area surrounding the display area DA.

The display area DA may be located on a surface of the display device DD1. In an example, the display area DA may be located on a front surface of the display device DD1. The display area DA may be additionally located on a side surface and a back surface of the display device DD1.

The non-display area NA may be located at the periphery of the display area DA to surround the display area DA, and selectively include lines, pads, a driving circuit, and the like, which are electrically connected to the pixels PXL of the display area DA.

The display device DD1 may include scan lines S1, . . . , Si, . . . , and Sn, control lines CL1, . . . , CLi, . . . , and CLn, data lines D1, . . . , Dj, . . . , and Dm, sensing lines SEN1, . . . , SENj, . . . , and SENm, and pixels PXL. A pixel PXL may be electrically connected to a scan line Si, a control line CLi, a data line Dj, and a sensing line SENj.

Although not shown in FIG. 2, the scan lines S1, . . . , Si, . . . , and Sn and the control lines CL1, . . . , CLi, . . . , and CLn may be electrically connected to a gate pad unit (or gate pad part) disposed at one side of the display device D1. Also, the data lines D1, . . . , Dj, . . . , and Dm and the sensing lines SEN1, . . . , SENj, . . . , and SENm may be electrically connected to a data pad part disposed at a side of the display device DD1.

In the display devices DD1, DD2, DD3, and DD4, an image displayed on a screen of the multi-screen display device TDD may be broken off due to the non-display area NA located in a boundary area between the display devices DD1, DD2, DD3, and DD4. In case that the non-display area NA has a relatively large width (or area), the breakoff of the image may be deepened in the boundary area between the display devices DD1, DD2, DD3, and DD4. The non-display area NA located in the boundary area between the display devices DD1, DD2, DD3, and DD4 may be referred to as a seam area, an assembly joint area, or a dead space area.

In case that the boundary area between the display devices DD1, DD2, DD3, and DD4 is visually recognized, the luminance of an image displayed on the screen of the multi-screen display device TDD may be deteriorated. A back surface bonding structure may be required, which can improve the color and luminance deviations of each display device and reduce the seam area such that the boundary area between the display devices DD1, DD2, DD3, and DD4 is not visually recognized. The back surface bonding structure refers to a structure in which, in each of the display devices DD1, DD2, DD3, and DD4, a chip on film (COF), a flexible printed circuit board, and the like are electrically connected to a lower surface of the display device DD1, DD2, DD3, or DD4. The back surface bonding structure for reducing a seam area will be described in detail below.

The pixels PXL may be provided in the display area DA. Each of the pixels PXL may be a minimum unit for displaying an image. Each of the pixels PXL may include a light emitting element emitting white light and/or colored light. Each of the pixels PXL may emit light of any one color among red, green, and blue. However, the disclosure is not limited thereto, and each of the pixels PXL may emit light of a color such as cyan, magenta, or yellow.

Although a case where the pixel PXL has a rectangular shape has been illustrated in the drawing, the disclosure is not limited thereto, and the shape of the pixel PXL may be variously modified. Each of the pixels PXL may include a pixel circuit layer PCL located on a base layer BSL which will be described below, a display element layer DPL located on the pixel circuit layer PCL, and the like.

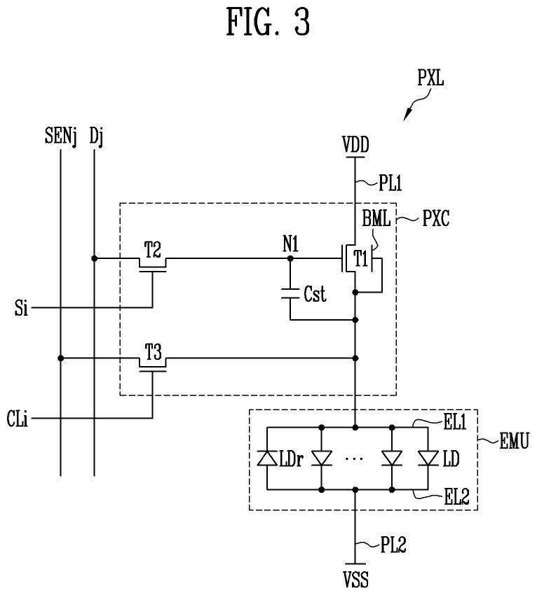

Hereinafter, a connection relationship of a pixel of a display device in accordance with an embodiment will be described with reference to FIG. 3.

FIG. 3 is a schematic diagram of an equivalent circuit illustrating a pixel of a display device in accordance with an embodiment.

Referring to FIG. 3, the pixel PXL may include at least one light emitting unit (light emitting part) EMU for generating light with a luminance corresponding to a data signal. The pixel PXL may selectively further include a pixel circuit PXC for driving the light emitting part EMU.

The light emitting part EMU may include light emitting elements LD electrically connected in parallel between a first power line PL1 to which a voltage of a first driving power source VDD is applied and a second power line PL2 to which a voltage of a second driving power source VSS is applied.

The light emitting part EMU may include a first electrode EL1 electrically connected to the first driving power source VDD via the pixel circuit PXC and the first power line PL1, a second electrode EL2 electrically connected to the second driving power source VSS through the second power line PL2, and light emitting elements LD electrically connected in parallel in a same direction between the first electrode EL1 and the second electrode EL2. In an embodiment, the first electrode EL1 may be an anode, and the second electrode EL2 may be a cathode.

Each of the light emitting elements LD included in the light emitting part EMU may include an end portion (or first end portion) electrically connected to the first driving power source VDD through the first electrode EL1 and the other end portion (or second end portion) electrically connected to the second driving power source VSS through the second electrode EL2.

The first driving power source VDD and the second driving power source VSS may have different potentials. In an example, the first driving power source VDD may be set as a high-potential power source, and the second driving power source VSS may be set as a low-potential power source. A potential difference between the first driving power source VDD and the second driving power source VSS may be set to be equal to or higher than a threshold voltage of the light emitting elements LD during an emission period of the pixel PXL.

As described above, the light emitting elements LD electrically connected in parallel in the same direction (e.g., a forward direction) between the first electrode EL1 and the second electrode EL2 to which voltages having different potentials are supplied, may form effective light sources, respectively. The effective light sources may constitute the light emitting part EMU of the pixel PXL.

In some embodiments, the light emitting part EMU may further include at least one ineffective light source, e.g., a reverse light emitting element LDr, in addition to the light emitting elements LD forming the respective effective light sources. The reverse light emitting element LDr along with the light emitting elements LD forming the effective light sources is electrically connected in parallel between the first electrode EL1 and the second electrode EL2, and may be electrically connected between the first electrode EL1 and the second electrode EL2 in a direction opposite to that in which the light emitting elements LD are electrically connected. Although a predetermined driving voltage (e.g., a forward driving voltage) is applied between the first electrode EL1 and the second electrode EL2, the reverse light emitting element LDr maintains an inactive state, and accordingly, no current substantially flows through the reverse light emitting element LDr.

The light emitting elements LD of the light emitting part EMU may emit light with a luminance corresponding to a driving current supplied through the pixel circuit PXC. For example, during each frame period, the pixel circuit PXC may supply, to the light emitting part EMU, a driving current corresponding to a grayscale value of one frame datum (or data). The driving current supplied to the light emitting part EMU may be divided and flow through the light emitting elements LD. Accordingly, the light emitting part EMU can emit light with a luminance corresponding to the driving current while each light emitting element LD emits light with a luminance corresponding to the driving current flowing therethrough.

Although FIG. 3 illustrates an embodiment in which the light emitting elements LD constituting the light emitting part EMU are all electrically connected in parallel, the disclosure is not limited thereto. In some embodiments, the light emitting part EMU may include two serial stages. In some embodiments, the light emitting elements LD may be electrically connected to each other in n serial stages. For example, the light emitting part EMU may be configured in a series-parallel hybrid structure.

The pixel circuit PXC may be electrically connected to a scan line Si and a data line Dj of the pixel PXL. In an example, in case that the pixel PXL is disposed on an i-th (i is a natural number) row and a j-th (j is a natural number) column of the display area DA (see FIG. 2), the pixel circuit PXC of the pixel PXL may be electrically connected to an i-th scan line Si and a j-th data line Dj of the display area DA. The pixel circuit PXC may be electrically connected to an i-th control line CLi and a j-th sensing line SENj of the display area DA.

The pixel circuit PXC may include a first transistor T1, a second transistor T2, a third transistor T3, and a storage capacitor Cst.

A first terminal of the first transistor T1 (or driving transistor) may be electrically connected to the first driving power source VDD, and a second terminal of the first transistor T1 may be electrically connected to the first electrode EL1 of the light emitting part EMU. A gate electrode of the first transistor T1 may be electrically connected to a first node N1. Accordingly, the first transistor T1 may control an amount of driving current supplied to the light emitting elements LD, corresponding to a voltage of the first node N1.

In an embodiment, the first transistor T1 may selectively include a bottom metal layer BML. The gate electrode of the first transistor T1 and the bottom metal layer BML may overlap each other with an insulating layer interposed therebetween, e.g., in a plan view.

A first terminal of the second transistor T2 (or switching transistor) may be electrically connected to the data line Dj, and a second terminal of the second transistor T2 may be electrically connected to the first node N1. A gate electrode of the second transistor T2 may be electrically connected to the scan line Si. The second transistor T2 may be turned on in case that a scan signal (high level) having a turn-on voltage is supplied from the scan line Si, to electrically connect the data line Dj and the first node N1 to each other. In case that a data signal of a frame is supplied to the data line Dj, the data signal is transmitted to the first node N1. The storage capacitor Cst may be changed with the data signal transmitted to the first node N1.

The third transistor T3 may be electrically connected between the first transistor T1 and the sensing line SENj. A first terminal of the third transistor T3 may be electrically connected to the first terminal of the first transistor T1, and a second terminal of the third transistor T3 may be electrically connected to the sensing line SENj. A gate electrode of the third transistor T3 may be electrically connected to the control line CLi. The third transistor T3 may be turned on by a control signal (high level) having a gate-on voltage, which is supplied to the control line CLi during a sensing period, to electrically connect the sensing line SENj and the first transistor T1 to each other. The sensing period may be a period in which characteristic information of each of the pixels PXL disposed in the display area DA (e.g., a threshold voltage of the first transistor T1, etc.) is extracted.

An electrode of the storage capacitor Cst may be electrically connected to the first node N1, and another electrode of the storage capacitor Cst may be electrically connected to the second terminal of the first transistor T1. The storage capacitor Cst may be charged with a voltage corresponding to a difference between a voltage corresponding to the data signal supplied to the first node N1 and a voltage of the second terminal of the first transistor T1, and maintain the charged voltage until a data signal of a next frame is supplied.

Although FIG. 3 illustrates an embodiment in which the first to third transistors T1 to T3 are N-type transistors, the disclosure is not limited thereto. In some embodiments, at least one of the first to third transistors T1 to T3 may be changed to a P-type transistor.

Although FIG. 3 illustrates an embodiment in which the light emitting part EMU is electrically connected between the pixel circuit PXC and the second driving power source VSS, the light emitting part EMU may also be electrically connected between the first driving power source VDD and the pixel circuit PXC.

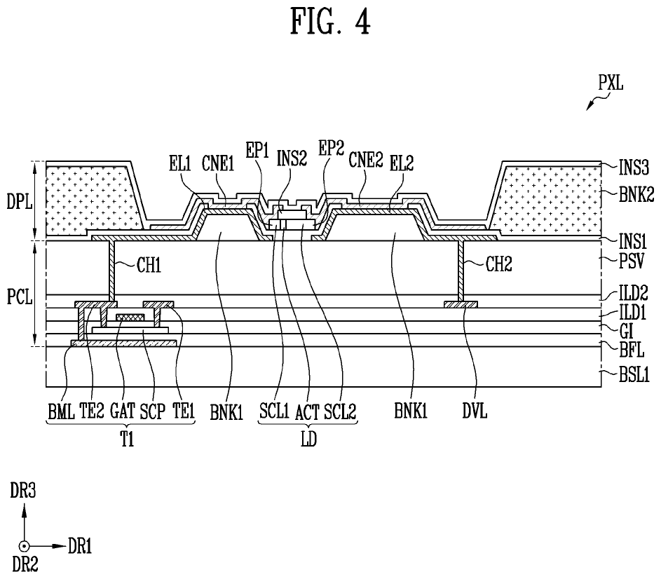

Hereinafter, a structure of a pixel of a display device in accordance with an embodiment will be described in detail with reference to FIGS. 4 to 6

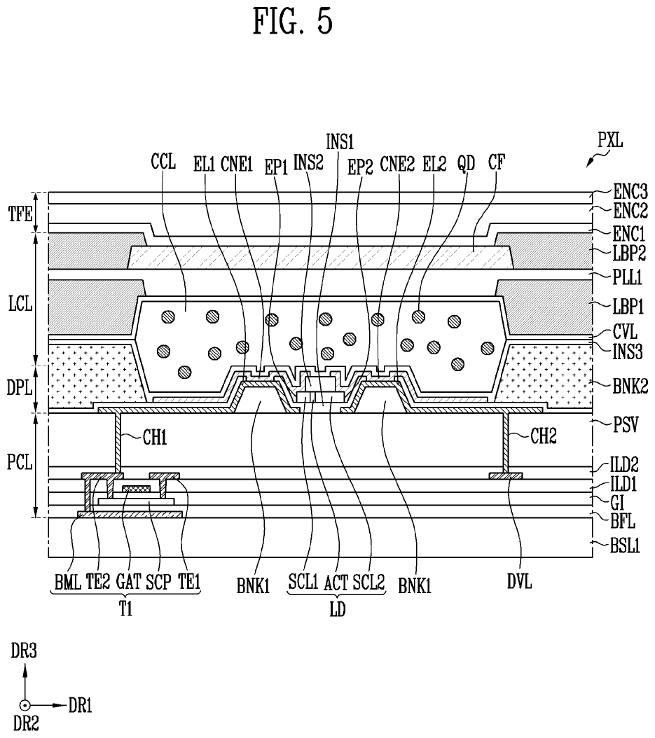

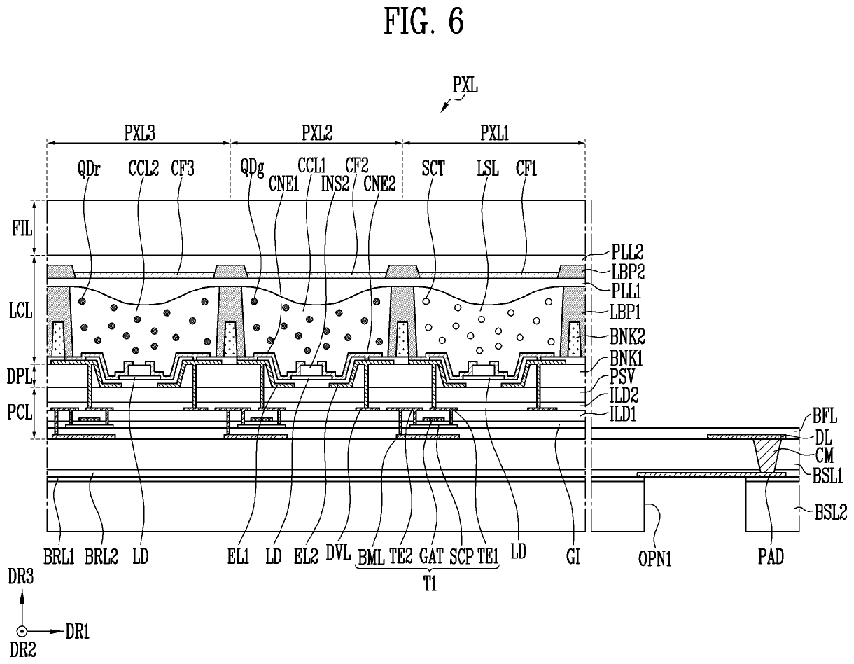

FIG. 4 is a schematic cross-sectional view mainly illustrating a pixel circuit layer and a display element layer of a pixel of a display device in accordance with an embodiment. FIG. 5 is a schematic cross-sectional view mainly illustrating a pixel circuit layer, a display element layer, a light conversion layer, and the like of a pixel of a display device in accordance with an embodiment. FIG. 6 is a schematic cross-sectional view mainly illustrating a pixel circuit layer, a display element layer, a light conversion layer, and the like of a display device in accordance with an embodiment.

First, referring to FIGS. 4 and 5, a pixel in accordance with an embodiment may include a first base layer BSL1, a pixel circuit layer PCL, a display element layer DPL, a light conversion layer LCL, and a thin-film encapsulation layer TFE.

The first base layer BSL1 may be a rigid or flexible substrate. For example, in case that the first base layer BSL1 is a rigid substrate, the first base layer BSL1 may be formed as a glass substrate, a quartz substrate, a glass ceramic substrate, a crystalline glass substrate, or the like. In case that the first base layer BSL1 is a flexible substrate, the first base layer BSL1 may be formed as a polymer organic substrate including polyimide, polyamide or the like, a plastic substrate, or the like.

A pixel circuit layer PCL is located on the first base layer BSL1.

The pixel circuit layer PCL may include at least one transistor, a storage capacitor, and lines electrically connected thereto. The pixel circuit layer PCL may include a buffer layer BFL, a gate insulating layer GI, a first interlayer insulating layer ILD1, a second interlayer insulating layer ILD2, and/or a passivation layer PSV, which are sequentially stacked on a surface of the first base layer BSL1.

A bottom metal layer BML is located on the first base layer BSL1. The bottom metal layer BML is located such that at least a portion of the bottom metal layer BML overlaps a semiconductor pattern SCP and a gate electrode GAT of a first transistor T1 which will be described below. The bottom metal layer BML may be electrically connected to a second electrode TE2 of the first transistor T1 through a contact hole of the buffer layer BFL, the gate insulating layer GI, and the first interlayer insulating layer ILD1. The second electrode TE2 of the first transistor T1 may be substantially identical or similar to the second terminal of the first transistor T1 shown in FIG. 3.

The buffer layer BFL is located on the first base layer BSL1 and the bottom metal layer BML. The buffer layer BFL may cover (or overlap) the first base layer BSL1 and the bottom metal layer BML. The buffer layer BFL may prevent an impurity from being diffused into the pixel circuit layer PCL from the outside. The buffer layer BFL may include at least one of silicon nitride (SiNₓ), silicon oxide (SiOₓ), silicon oxynitride (SiOₓN_{y}), and metal oxide such as aluminum oxide (AlOₓ). For example, the buffer layer BFL may have a thickness of about 5000 Å. In some embodiments, the buffer layer BFL may be omitted.

The semiconductor pattern SCP of the first transistor T1 is located on the buffer layer BFL. The semiconductor pattern SCP may include a channel region, and a source region and a drain region which are located at both sides of the channel region. The source region of the semiconductor pattern SCP may be electrically connected to the second electrode TE2, and the drain region of the semiconductor pattern SCP may be electrically connected to a first electrode TE1. For example, the source region and the drain region may extend to be electrically connected to electrodes of another layer through contact holes, respectively.

The semiconductor pattern SCP may include at least one of polysilicon, amorphous silicon, and an oxide semiconductor.

The gate insulating layer GI is located on the semiconductor pattern SCP and the buffer layer BFL. The gate insulating layer GI covers (or overlaps) the semiconductor pattern SCP and the buffer layer BFL. The gate insulating layer GI may include an inorganic material. In an example, the gate insulating layer GI may include at least one of silicon nitride (SiNₓ), silicon oxide (SiOₓ), silicon oxynitride (SiOₓN_{y}), and aluminum oxide (AlOₓ). In some embodiments, the gate insulating layer GI may include an organic material.

The gate electrode GAT of the first transistor T1 is located on the gate insulating layer GI. The gate electrode GAT may be located to overlap the channel region of the semiconductor pattern SCP.

The first interlayer insulating layer ILD1 is located on the gate electrode GAT and the gate insulating layer GI. The first interlayer insulating layer ILD1 covers the gate electrode GAT and the gate insulating layer GI.

The first interlayer insulating layer ILD1 and the gate insulating layer GI may include the same material. In an example, the first interlayer insulating layer ILD1 may include at least one of silicon nitride (SiNₓ), silicon oxide (SiOₓ), silicon oxynitride (SiOₓN_{y}), and aluminum oxide (AlOₓ).

The first electrode TE1 and the second electrode TE2 of the first transistor T1 are located on the first interlayer insulating layer ILD1. The first electrode TE1 may be a drain electrode electrically connected to the drain region of the semiconductor pattern SCP, and the second electrode TE2 may be a source electrode electrically connected to the source region of the semiconductor pattern SCP. The first electrode TE1 may be substantially identical or similar to the first terminal of the first transistor T1 shown in FIG. 3. Accordingly, the first electrode TE1 may be applied with the voltage of the first driving power source VDD (see FIG. 3) through the first power line PL1 (see FIG. 3). The second electrode TE2 may be physically and/or electrically connected to a first electrode EL1 of the display element layer DPL which will be described below through a first contact hole CH1. Therefore, the first transistor T1 may transfer the voltage of the first driving power source VDD to the first electrode EL1. In some embodiments, the first electrode TE1 may be the source electrode, and the second electrode TE2 may be the drain electrode.

A driving voltage line DVL is located on the first interlayer insulating layer ILD1. The driving voltage line DVL and a portion of the second power line PL2 shown in FIG. 3 may have the same configuration. The driving voltage line DVL may be physically and/or electrically connected to a second electrode EL2 of the display element layer DPL which will be described below through a second contact hole CH2. Therefore, the driving voltage line DVL may transmit the voltage of the second driving power source VSS (see FIG. 3) to the second electrode EL2.

The second interlayer insulating layer ILD2 is located on the first interlayer insulating layer ILD1, the first electrode TE1 of the first transistor T1, the second electrode TE2 of the first transistor T1, and the driving voltage line DVL. The second interlayer insulating layer ILD2 covers (or overlaps) the first interlayer insulating layer ILD1, the first electrode TE1 of the first transistor T1, the second electrode TE2 of the first transistor T1, and the driving voltage line DVL.

The second interlayer insulating layer ILD2 may include at least one of silicon oxide (SiOₓ), silicon nitride (SiNₓ), and silicon oxynitride (SiOₓN_{y}). In some embodiments, the second interlayer insulating layer ILD2 may be an organic insulating layer including an organic material.

The passivation layer PSV is located on the second interlayer insulating layer ILD2. The passivation layer PSV may include at least one organic insulating layer and substantially planarize a surface of the pixel circuit layer PCL. The passivation layer PSV may be configured as a single layer or a multi-layer and include an inorganic insulating material and an organic insulating material. For example, the passivation layer PSV may include at least one of polyacrylates resin, epoxy resin, phenolic resin, polyamides resin, and polyimides resin.

The display element layer DPL is located on the pixel circuit layer PCL including the passivation layer PSV. The first contact hole CH1 of the passivation layer PSV may electrically connect the second electrode TE2 of the first transistor T1 and the first electrode EL1 of the display element layer DPL to each other therethrough. The driving voltage line DVL and the second electrode EL2 of the display element layer DPL may be electrically connected to each other through the second contact hole CH2 of the passivation layer PSV.

The display element layer DPL may include a light emitting element LD of each pixel PXL and electrodes electrically connected to the light emitting element LD. The light emitting element may be a micro inorganic light emitting diode small to a degree of nanometer scale or micrometer scale, which are manufactured by growing a nitride-based semiconductor. In an embodiment, each light emitting element LD may be a micro inorganic light emitting diode having a pillar or columnar shape with an aspect ratio of greater than 1, but the disclosure is not limited thereto.

The display element layer DPL may include a first bank BNK1, a second bank BNK2, the first electrode EL1, and the second electrode EL2, a first insulating layer INS1, the light emitting element LD, a second insulating layer INS2, a first contact electrode CNE1, a second contact electrode CNE2, and a third insulating layer INS3.

The first bank BNK1 is located on the passivation layer PSV. The first bank BNK1 may be disposed on the bottom of portions of the first electrode EL1 and the second electrode EL2 to guide light emitted from the light emitting element LD in an image display direction of the display device (e.g., an upper direction of each pixel PXL, e.g., a third direction DR3), so that the portions of the first electrode EL1 and the second electrode EL2 can protrude in the upper direction, e.g., the third direction DR3

The first bank BNK1 may include an inorganic insulating layer made of an inorganic material or an organic insulating layer made of an organic material. In some embodiments, the first bank BNK1 may include a single-layered organic insulating layer or a single-layered inorganic insulating layer, but the disclosure is not limited thereto.

The second bank BNK2 is located on the passivation layer PSV. The second bank BNK2 is a structure for defining an emission area of each of the pixels PXL and may be located in a non-emission area of each pixel PXL to surround the emission area of each pixel PXL. For example, the second bank BNK2 may be a pixel defining layer or a dam structure. The second bank BNK2 may include at least one light blocking material and at least one reflective material. In some embodiments, the second bank BNK2 may be implemented as a dam structure which overlaps a first light blocking part LBP1 which will be described below, to determine an area in which light emitting elements LD are supplied (or input) in each pixel PXL.

Each of the first electrode EL1 and the second electrode EL2 is located on the first bank BNK1 and has a surface corresponding to the shape of the first bank BNK1. The first electrode EL1 and the second electrode EL2 may include a material having a uniform reflexibility. Accordingly, the first electrode EL1 and the second electrode EL2 enable light emitted from the light emitting element LD to advance in the image display direction of the display device (e.g., the third direction DR3). In an embodiment, the first electrode EL1 may be an anode, and the second electrode EL2 may be a cathode.

The first insulating layer INS1 is located between the passivation layer PSV and each of the first electrode EL1 and the second electrode EL2. The first insulating layer INS1 may fill a space between the light emitting element LD and the passivation layer PSV to stably support the light emitting element LD. The first insulating layer INS1 may include at least one material selected from an inorganic insulating layer and an organic insulating layer and be configured as a single layer or a multi-layer.

The light emitting element LD is located on the first insulating layer INS1. At least one light emitting element LD may be disposed between the first electrode EL1 and the second electrode EL2. In some embodiments, light emitting elements LD may be disposed between the first electrode EL1 and the second electrode EL2 and be electrically connected in parallel to each other.

Each of the light emitting elements LD may emit light of any one of a color, white, and blue. In an embodiment, the light emitting elements LD may be provided in a form which can be sprayed in a solution to be input to each pixel PXL.

The light emitting element LD may include a first semiconductor layer SCL1, an active layer ACT, and a second semiconductor layer SCL2, which are sequentially disposed in the first direction DR1. The light emitting element LD may further include an insulative film (not shown) surrounding outer circumferential surfaces of the first semiconductor layer SCL1, the active layer ACT, and the second semiconductor layer SCL2.

The first semiconductor layer SCL1 may include a first conductivity type semiconductor. For example, the first semiconductor layer SCL1 may include at least one P-type semiconductor layer. In an example, the first semiconductor layer SCL1 may include at least one semiconductor material among InAlGaN, GaN, AlGaN, InGaN, AlN, and InN and include a P-type semiconductor layer doped with a first conductivity type dopant (or P-type dopant) such as Mg.

The active layer ACT may be formed in a single-quantum well structure or a multi-quantum well structure. In some embodiments, a material such as AlGaN or AlInGaN may be used to form the active layer ACT. The active layer ACT may be formed of various materials. The position of the active layer ACT may be variously changed according to the kind of the light emitting element LD. The active layer ACT may emit light having a wavelength of about 400 nm to about 900 nm and use a double hetero-structure.

The second semiconductor layer SCL2 may include a semiconductor layer having a type different from that of the first semiconductor layer SCL1. For example, the second semiconductor layer SCL2 may include at least one N-type semiconductor layer. In an example, the second semiconductor layer SCL2 may include any one semiconductor material among InAlGaN, GaN, AlGaN, InGaN, AlN, and InN and be an N-type semiconductor layer doped with a second conductivity type dopant (or an N-type dopant) such as Si, Ge, or Sn.

An end portion in the direction of the first semiconductor layer SCL1 may be referred to as a first end portion EP1 of the light emitting element LD, and the other end portion in the direction of the second semiconductor layer SCL2 may be referred to as a second end portion EP2 of the light emitting element LD.

The second insulating layer INS2 is located on a portion of the light emitting element LD. The second insulating layer INS2 covers a portion of a top surface of each light emitting element LD and exposes the first end portion EP1 and the second end portion EP2 of the light emitting element LD. The second insulating layer INS2 may stably fix the light emitting element LD. In case that an empty space exists between the first insulating layer INS1 and the light emitting element LD before the second insulating layer INS2 is formed, the empty space may be at least partially filled with the second insulating layer INS2.

The first contact electrode CNE1 is located on the first electrode ELL and the first contact electrode CNE1 physically and/or electrically connects the first electrode EL1 to an end portion (e.g., the first end portion EP1) of the light emitting element LD. The first contact electrode CNE1 may be located to overlap portions of the first insulating layer INS1, the second insulating layer INS2, the first electrode ELL and the light emitting element LD. The first insulating layer INS1 may be removed from a portion at which the first electrode EL1 and the first contact electrode CNE1 are electrically connected to each other, e.g., a portion at which the first electrode EL1 and the first contact electrode CNE1 directly contact each other.

The second contact electrode CNE2 is located on the second electrode EL2, and the second contact electrode CNE2 physically and/or electrically connect the second electrode EL2 to an end portion (e.g., the second end portion EP2) of the light emitting element LD. The second contact electrode CNE2 may be located to overlap portions of the first insulating layer INS1, the second insulating layer INS2, the second electrode EL2, and the light emitting element LD. The first insulating layer INS may be removed from a portion at which the second electrode EL2 and the second contact electrode CNE2 are electrically connected to each other, e.g., a portion at which the second electrode EL2 and the second contact electrode CNE2 directly contact each other.

The first contact electrode CNE1 and the second contact electrode CNE2 may be made of a transparent conductive material. For example, the first contact electrode CNE1 and the second contact electrode CNE2 may include a material such as indium tin oxide (ITO), indium zinc oxid (IZO), or indium tin zinc oxide (ITZO). Accordingly, the first contact electrode CNE1 and the second contact electrode CNE2 enable light which is emitted from the light emitting element LD and then reflected by the first electrode EL1 and the second electrode EL2 to advance in the image display direction of the display device (e.g., the third direction DR3).

The third insulating layer INS3 is located over the first contact electrode CNE1, the second contact electrode CNE2, and the second bank BNK2. The third insulating layer INS3 may include at least one organic layer and at least one inorganic layer and be entirely located on a surface of the display element layer DPL.

Referring to FIG. 5, the light conversion layer LCL is located on the display element layer DPL.

The light conversion layer LCL may include at least one of a color conversion layer CCL including a quantum dot QD (e.g., red quantum dot QDr or green quantum dot QDg) and a color filter CF located on the display element layer DPL or the color conversion layer CCL. The light conversion layer LCL may further include the color conversion layer CCL, a cover layer CVL, the first light blocking part LBP1, a first planarization layer PLL1, the color filter CF, and a second light blocking part LBP2, which are sequentially disposed on the display element layer DPL.

The color conversion layer CCL is disposed above the light emitting element LD and may include color conversion particles (e.g., the quantum dot QD of a color) for converting light of a first color, which is emitted from the light emitting element LD, into light of a second color.

For example, in case that at least one pixel PXL is set as a pixel PXL of red (or green), and a blue light emitting element LD is disposed as a light source of the pixel PXL, a color conversion layer CCL including a quantum dot QD of red (or green) for converting light of blue into light of red (or green) may be disposed at an upper portion of the pixel PXL. A color filter CF of red (or green) may be disposed above the color conversion layer CCL.

The cover layer CVL for protecting the color conversion layer CCL may be located over the color conversion layer CCL. The first light blocking part LBP1 may be disposed on an area corresponding to the outside of the color conversion layer CCL.

The first planarization layer PLL1 may be located on the cover layer CVL and the first light blocking part LBP1. The first planarization layer PLL1 may planarize top surfaces of the color conversion layer CCL and the first light blocking part LBP1 and include an organic material or an inorganic material.

The color filter CF may be disposed in the emission area in which light is emitted in each pixel PXL. The color filter CF may include a color filter material which allows light of a color corresponding to that of each pixel to be selectively transmitted therethrough. The second light blocking part LBP2 may be disposed at the outside of the color filter CF.

The thin-film encapsulation layer TFE is located on the light conversion layer LCL.

The thin-film encapsulation layer TFE may be configured as a single layer or a multi-layer. The thin-film encapsulation layer TFE may include insulating layers covering the display element layer DPL. In an example, the thin-film encapsulation layer TFE may include at least one inorganic layer and at least one organic layer. For example, the thin-film encapsulation layer TFE may have a structure in which an inorganic layer and an organic layer are alternately stacked.

The thin-film encapsulation layer TFE may include a first encapsulation layer ENC1, a second encapsulation layer ENC2, and a third encapsulation layer ENC3. For example, the first encapsulation layer ENC1 and the third encapsulation layer ENC3 may be configured as an inorganic layer including an inorganic material, and the second encapsulation layer ENC2 may be configured as an organic layer including an organic material.

Referring to FIG. 6, a display device in accordance with an embodiment may include a first base layer BSL1, a pixel circuit layer PCL, a display element layer DPL, a light conversion layer LCL, a film layer FIL, a second base layer BSL2, a first barrier layer BRL1, a second barrier layer BRL2, and a pad electrode PAD. The first base layer BSL1, the pixel circuit layer PCL, and the display element layer DPL, which are shown in FIG. 6, are substantially similar to those described with reference to FIGS. 4 and 5, and therefore, differences therebetween will be mainly described below.

The first base layer BSL1 may further include an opening, and a conductive material CM may be filled in the opening of the first base layer BSL1. The conductive material CM may electrically connect a data line DL which will be described below and the pad electrode PAD to each other.

The pixel circuit layer PCL may further include the data line DL located between the first base layer BSL1 and a buffer layer BFL. The data line DL may correspond to a portion of the data line(s) DL shown in FIGS. 2 and 3.

The data line DL may be electrically connected to the pad electrode PAD through the conductive material CM filled in the opening of the first base layer BSL1.

The pixel circuit layer PCL may include a first transistor T1, and the first transistor T1 may include a bottom metal layer BML, a semiconductor pattern SCP, a gate electrode GAT, a first electrode TE1, and a second electrode TE2. The second electrode TE2 may be electrically connected to a source region of the semiconductor pattern SCP, and the first electrode TE1 may be electrically connected to a drain region of the semiconductor pattern SCP. The first transistor T1 may be a P-type transistor. Accordingly, the first electrode TE1 of the first transistor T1 may be physically and/or electrically connected to a first electrode EL1 of the display element layer DPL.

The pixel PXL may include a first sub-pixel PXL1, a second sub-pixel PXL2, and a third sub-pixel PXL3.

The light conversion layer LCL may include first to third color filters CF1, CF2, and CF3 which correspond to colors of the first to third sub-pixels PXL1, PXL2, and PXL3.

The first color filter CF1 may be disposed at an upper portion of the first sub-pixel PXL1 to allow light generated from the first sub-pixel PXL1 to be selectively transmitted therethrough. For example, the first color filter CF1 may be a blue color filter.

The second color filter CF2 may be disposed at an upper portion of the second sub-pixel PXL2 to allow light generated from the second sub-pixel PXL2 to be selectively transmitted therethrough. For example, the second color filter CF2 may be a green color filter.

The third color filter CF3 may be disposed at an upper portion of the third sub-pixel PXL3 to allow light generated from the third sub-pixel PXL3 to be selectively transmitted therethrough. For example, the third color filter CF3 may be a red color filter.

A first light blocking part LBP1 is a part for blocking light and is located over a second bank BNK2. The first light blocking part LBP1 may be located each of between a light scattering layer LSL including scatterers SCT and a first color conversion layer CCL1, between the first color conversion layer CCL1 and a second color conversion layer CCL2, and the like. The first light blocking part LBP1 and the second bank BNK2 may be made of the same material, but the disclosure is not limited thereto. The first light blocking part LBP1 along with the second bank BNK2 may have a dam structure which determines an area in which light emitting elements LD are supplied in the first to third sub-pixels PXL1, PXL2, and PXL3.

A second light blocking part LBP2 is a part for blocking light and is located on a first planarization layer PLL1. The second light blocking part LBP2 may be located between the first color filter CF1 and the second color filter CF2 and between the second color filter CF2 and the third color filter CF3.

In some embodiments, the second light blocking part LBP2 may be configured such that portions of at least two of the first color filter CF1, the second color filter CF2, and the third color filter CF3 overlap each other. For example, the second light blocking part LBP2 located between the first color filter CF1 and the second color filter CF2 may include a portion of the first color filter CF1, a portion of the third color filter CF3, and a portion of the second color filter CF2, and the portions of the first to third color filters CF1, CF2, and CF3 may be stacked to block light. The second light blocking part LBP2 located between the second color filter CF2 and the third color filter CF3 may include a portion of the first color filter CF1 and a portion of the third color filter CF3, and the portions of the first and third color filters CF1 and CF3 may be stacked to block light.

A second planarization layer PLL2 may be located on the first to third color filters CF1, CF2, and CF3 and the second light blocking part LBP2. The second planarization layer PLL2 may planarize top surfaces of the first to third color filters CF1, CF2, and CF3 and the second light blocking part LBP2 and include an organic material or an inorganic material.

The film layer FIL is located on the second planarization layer PLL2 and may be a film layer which prevents reflection of light incident from the outside. For example, the film layer FIL may include a protective film, tri-acetyl-cellulose (TAC), and a pressure-sensitive adhesive (PSA).

In some embodiments, a thin-film encapsulation layer may be located between the second planarization layer PLL2 and the film layer FIL, and the film layer FIL may be omitted.

The second base layer BSL2 is located under the first base layer BSL1 and may include a first opening OPN1. A chip on film may be electrically connected to the display device through the first opening OPN1.

The first barrier layer BRL1 and the second barrier layer BRL2 may be located between the first base layer BSL1 and the second base layer BSL2.

The pad electrode PAD may be located between the first base layer BSL1 and the second base layer BSL2.

The pad electrode PAD may be electrically connected to the data line DL through the conductive material CM.

In some embodiments, a lower film and a heat dissipation film may be located under the second base layer BSL2. In addition, a chip on film may be located between the second base layer BSL2 and the lower film and be located on the bottom of the heat dissipation film. In some embodiments, the positions of the lower film, the heat dissipation film, and the chip on film of the display device may be variously changed.

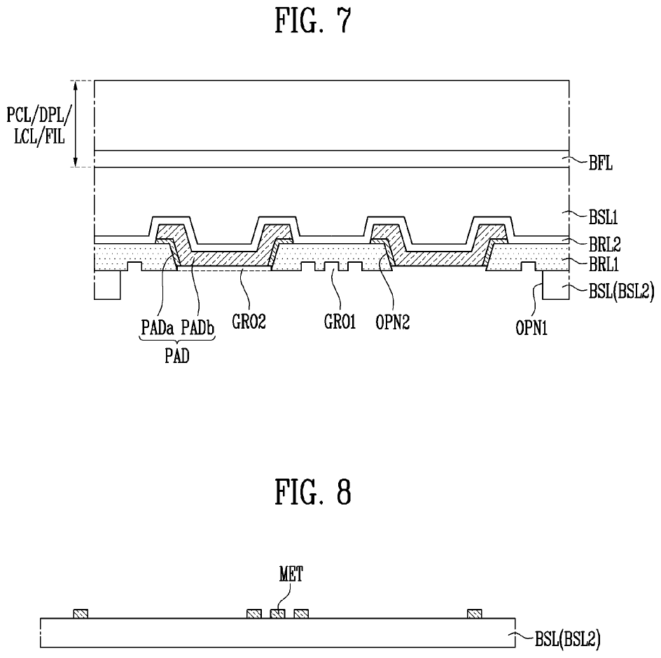

Hereinafter, a display device and a manufacturing method of the same in accordance with an embodiment will be described with reference to FIGS. 7 to 10.

FIG. 7 is a schematic cross-sectional view illustrating a display device in accordance with an embodiment. FIGS. 8 to 10 are schematic views sequentially illustrating a manufacturing method of the display device shown in FIG. 7.

Referring to FIG. 7, the display device may include a second base layer BSL2, a first barrier layer BRL1, a pad electrode PAD, a second barrier layer BRL2, a first base layer BSL1, a buffer layer BFL, a pixel circuit layer PCL, a display element layer DPL, a light conversion layer LCL, and a film layer FIL. The first base layer BSL1, the buffer layer BFL, the pixel circuit layer PCL, the display element layer DPL, the light conversion layer LCL, and the film layer FIL are substantially identical or similar to those described with reference to FIG. 6, and therefore, repetitive descriptions thereof will be omitted.

The second base layer BSL2 (or base layer BSL) may be a rigid or flexible substrate. For example, in case that the second base layer BSL2 is a rigid substrate, the second base layer BSL2 may be implemented as a glass substrate, a quartz substrate, a glass ceramic substrate, a crystalline glass substrate, or the like. In case that the second base layer BSL2 is a flexible substrate, the second base layer BSL2 may be implemented as a polymer organic substrate including polyimide, polyamide or the like, a plastic substrate, or the like.

The second base layer BSL2 may include a first opening OPN1. The first opening OPN1 of the second base layer BSL2 may expose at least one surface (e.g., a lower surface) of the first barrier layer BRL1 which will be described below and at least one surface (e.g., a lower surface) of the pad electrode PAD which will be described below. The first opening OPN1 of the second base layer BSL2 may expose a first groove GRO1 formed at the lower surface of the first barrier layer BRL1 and a second groove GRO2 formed at the lower surface of the pad electrode PAD.

The pad electrode PAD and a chip on film may be electrically connected to each other through the first opening OPN1 of the second base layer BSL2.

The first barrier layer BRL1 is located on a surface of the second base layer BSL2. For example, the first barrier layer BRL1 may be located on a top surface of the second base layer BSL2. The first barrier layer BRL1 may include at least one of amorphous silicon and metal oxide such as silicon oxide (SiOₓ). For example, the first barrier layer BRL1 may have a thickness of about 6000 Å. However, the disclosure is not limited thereto.

The first barrier layer BRL1 may include a second opening OPN2. At least a portion of the pad electrode PAD which will be described below may be located in the second opening OPN2 of the first barrier layer BRL1.

The first barrier layer BRL1 may include at least one first groove GRO1 formed at a surface thereof. The first groove GRO1 may be formed at the lower surface of the first barrier layer BRL1, and the lower surface of the first barrier layer BRL1, at which the first groove GRO1 is formed, may be disposed in the first opening OPN1 of the second base layer BSL2. For example, the at least one first groove GRO1 formed on the first barrier layer BRL1 may be exposed to the outside. In some embodiments, a desiccant, a vibration resistance agent, etc. may be located in the first groove GRO1.

The pad electrode PAD is located on the first barrier layer BRL1 and is located to cover (or overlap) the second opening OPN2 of the first barrier layer BRL1. For example, the pad electrode PAD may overlap at least a portion of the top surface of the first barrier layer BRL1 and overlap at least a portion of a side surface of the first barrier layer BRL1 through the second opening OPN2.

The pad electrode PAD may include a first layer PADa and a second layer PADb. For example, the first layer PADa may be made of titanium (Ti), and the second layer PADb may be made of copper (Cu). The first layer PADa may have a thickness of about 200 Å, and the second layer PADb may have a thickness of about 3000 Å. However, the disclosure is not limited thereto, and the material forming the pad electrode PAD may be variously changed in some embodiments. The thickness of the pad electrode PAD may be variously changed.

The pad electrode PAD may include the second groove GRO2 formed at a surface thereof. The second groove GRO2 may be formed at a lower surface of the second layer PADb of the pad electrode PAD disposed in the second opening OPN2 of the first barrier layer BRL1. In an embodiment, as the first layer PADa of the pad electrode PAD disposed in the second opening OPN2 of the first barrier layer BRL1 is removed by an atmospheric pressure plasma process, the second groove GRO2 may be formed at the lower surface of the pad electrode PAD disposed in the second opening OPN2 of the first barrier layer BRL1.

A connection ball (or solder ball) may be located in the second groove GRO2 of the pad electrode PAD to electrically connect the chip on film and the pad electrode PAD to each other. For example, in an embodiment, since the second groove GRO2 is formed at the lower surface of the pad electrode PAD, a spot (or point) at which the connection ball is disposed in a jet soldering process can be easily detected, and connection balls can be prevented from being arbitrarily distributed on the lower surface of the display device. Thus, the connection ball electrically connecting the pad electrode PAD and the chip on film to each other is stably disposed, so that a short circuit between the pad electrode PAD and the chip on film can be prevented.

In an embodiment, the jet soldering process may be used to electrically connect the pad electrode PAD and the chip on film to each other, so that damage to a display panel can be prevented.

The second barrier layer BRL2 are located on surfaces of the first barrier layer BRL1 and the pad electrode PAD. For example, the second barrier layer BRL2 may be located on the first barrier layer BRL1 and the pad electrode PAD. The second barrier layer BRL2 may cover an upper surface of the first barrier layer BRL1 and an upper surface of the pad electrode PAD.

The second barrier layer BRL2 may include at least one of silicon nitride (SiNₓ), silicon oxide (SiOₓ), silicon oxynitride (SiOₓN_{y}), and metal oxide such as aluminum oxide (AlOₓ) and be configured as a single layer or a multi-layer. For example, the second barrier layer BRL2 may be configured as a double layer including silicon nitride (SiNₓ) and silicon oxide (SiOₓ). A first layer of the second barrier layer BRL2, which is made of silicon nitride (SiNₓ), may have a thickness of about 300 Å, and a second layer of the second barrier layer BRL2, which is made of silicon oxide (SiOₓ), may have with a thickness of about 2000 Å. However, the disclosure is not limited thereto. The second barrier layer BRL2 may include various materials and have various thicknesses.

The first base layer BSL1, the buffer layer BFL, the pixel circuit layer PCL, the display element layer DPL, the light conversion layer LCL, and the film layer FIL may be sequentially located on the second barrier layer BRL2. However, the disclosure is not limited thereto. In some embodiments, at least one of the buffer layer BFL, the light conversion layer LCL, and the film layer FIL may be omitted.

Referring to FIG. 8, a base layer BSL is prepared, and at least one metal part MET is formed on a surface of the base layer BSL. The at least one metal part MET may be formed by depositing a metal material on the base layer BSL and patterning the deposited metal material by a photolithography process including exposure, development, wet etching, and the like.

The metal part MET may include a metal material. For example, the metal part MET may include a material such as titanium (Ti), but the disclosure is not limited thereto.

The metal part MET is used to form a first groove GRO1 at a lower surface of a first barrier layer BRL1. The metal part MET may be formed to correspond to the position, shape, size, etc., of the first groove GRO1. For example, as illustrated in FIG. 8, three metal parts MET are located adjacent to each other, and two metal parts MET is located while being spaced apart from the three adjacent metal parts MET. However, the disclosure is not limited thereto. In some embodiments, the position, shape, size, etc. of the metal part MET may be variously changed.

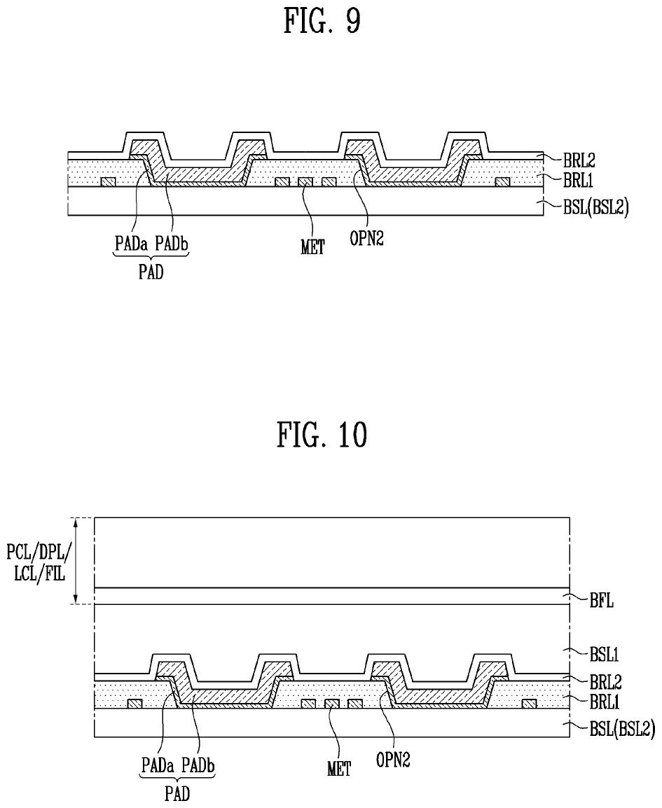

Referring to FIG. 9, the first barrier layer BRL1, a pad electrode PAD, and a second barrier layer BRL2 may be sequentially formed on the base layer BSL and the metal part MET.

First, a second opening OPN2 may be formed in the first barrier layer BRL1 by entirely depositing the first barrier layer BRL1 on the base layer BSL and the metal part MET and patterning the deposited first barrier layer BRL1 by a photolithography process including exposure, development, wet etching, and the like.

The pad electrode PAD may be formed by depositing a pad electrode material on the first barrier layer BRL1 and patterning the deposited pad electrode material by a photolithography process including exposure, development, wet etching, and the like. The pad electrode PAD may be located in the second opening OPN2 of the first barrier layers BRL1, and a lower surface (e.g., a first layer PADa) of the pad electrode PAD, which is formed in the second opening OPN2 of the first barrier layer BRL1, may contact a top surface of the base layer BSL.

Subsequently, the second barrier layer BRL2 may be deposited to cover (or overlap) surfaces of the first barrier layer BRL1 and the pad electrode PAD.

Referring to FIG. 10, a first base layer BSL1, a buffer layer BFL, a pixel circuit layer PCL, a display element layer DPL, a light conversion layer LCL, and a film layer FIL may be sequentially formed on the second barrier layer BRL2.

A method for forming the first base layer BSL1, the buffer layer BFL, the pixel circuit layer PCL, the display element layer DPL, the light conversion layer LCL, and the film layer FIL is substantially identical or similar to a manufacturing method of a general display device, and therefore, detailed descriptions thereof will be omitted.

Referring back to FIG. 7, a first opening OPN1 is formed in the base layer BSL, the first groove GRO1 is formed at the lower surface of the first barrier layer BRL1 by removing the metal part MET, and a second groove GRO2 is formed at a lower surface of the pad electrode PAD by removing a portion of the pad electrode PAD. In this case, an atmospheric pressure plasma process may be used.

In an embodiment, as the metal part MET disposed on the bottom of the first barrier layer BRL1 is removed by the atmospheric pressure plasma process, the first groove GRO1 may be formed at the lower surface of the first barrier layer BRL1. As the first layer PADa of the pad electrode PAD disposed in the second opening OPN2 of the first barrier layer BRL1 is removed by the atmospheric pressure plasma process, the second groove GRO2 may be formed at the lower surface of the pad electrode PAD disposed in the second opening OPN2 of the first barrier layer BRL1.

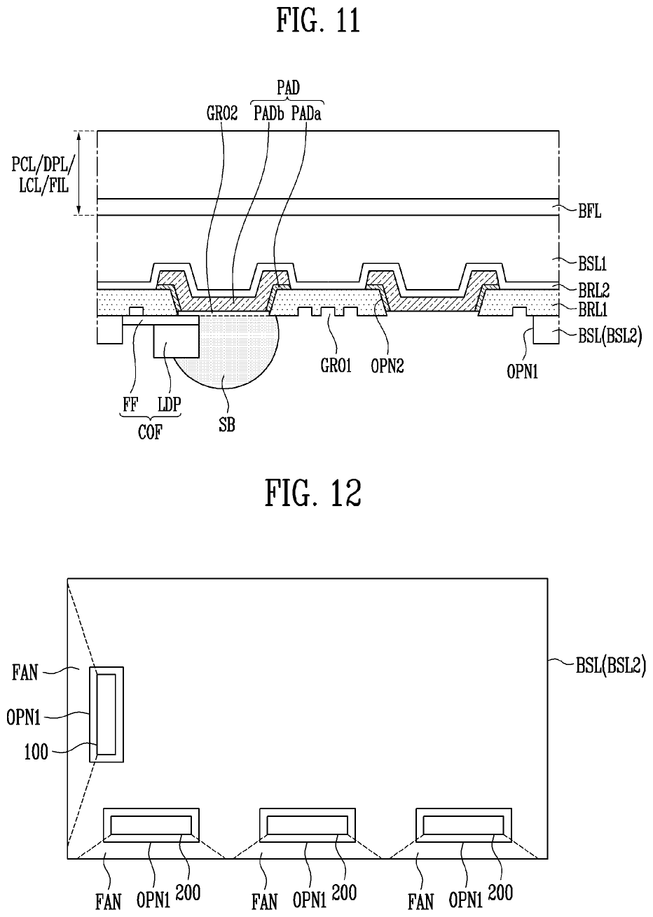

Hereinafter, a state in which a chip on film is attached to a display device in accordance with an embodiment will be described with reference to FIGS. 11 to 13.

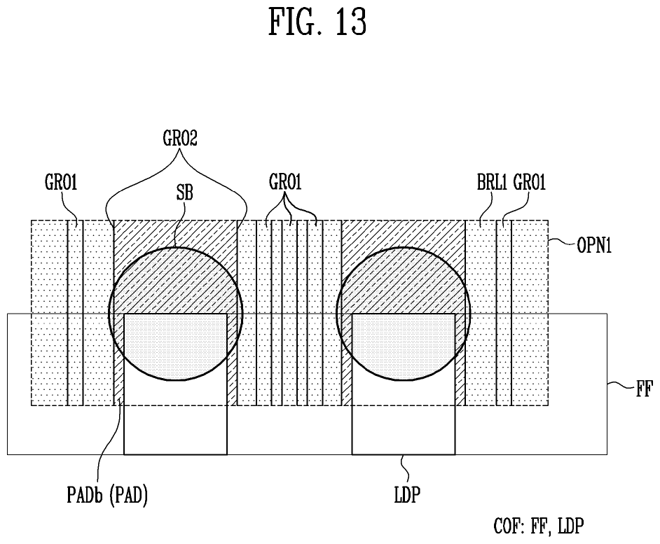

FIG. 11 is a schematic cross-sectional view illustrating a state in which a chip on film is attached to a display device in accordance with an embodiment. FIG. 12 is a rear view schematically illustrating a state in which a first opening is formed on a base layer of a display device in accordance with an embodiment. FIG. 13 is a schematic rear view illustrating a state in which a chip on film is attached to a display device in accordance with an embodiment.

First, referring to FIG. 11, the display device in accordance with the embodiment may further include a chip on film COF and a connection ball SB in the display device shown in FIG. 7.

The chip on film COF may include a flexible film FF and a lead part LDP provided on the flexible film FF. The chip on film COF may electrically connect a pad electrode PAD of the display device and a flexible printed circuit board to each other.

The flexible film FF and the lead part LDP may be located on a surface of a first barrier layer BRL1 and a surface of the pad electrode PAD. The flexible film FF may be located such that at least a portion of the flexible film FF overlaps a lower surface of the first barrier layer BRL1, and may be located such that at least a portion of the flexible film FF overlaps a lower surface of the pad electrode PAD.

Although the flexible film FF directly contacts the lower surface of the first barrier layer BRL1, the flexible film FF may prevent a step difference between the flexible film FF and a display panel, which may occur in case that the lower surface of the first barrier layer BRL1 and the flexible film FF directly contact each other, by means of a first groove GRO1 formed at the lower surface of the first barrier layer BRL1.

The connection ball SB is located such that at least a portion of the connection ball SB overlaps the lower surface of the pad electrode PAD and the chip on film COF. The connection ball SB may be provided on a side surface of the chip on film COF. The connection ball SB contacts both the pad electrode PAD and the chip on film COF to electrically connect the pad electrode PAD and the chip on film COF to each other.

The connection ball SB may be provided on a lower surface of the pad electrode PAD to correspond to a second groove GRO2 in a jet soldering process.

In an embodiment, since the second groove GRO2 is formed at the lower surface of the pad electrode PAD, a spot at which the connection ball SB is disposed in the jet soldering process can be easily detected, and connection balls SB can be prevented from being arbitrarily distributed on a lower surface of the display device. Thus, the connection ball SB electrically connecting the pad electrode PAD and the chip on film COF is stably disposed, so that a short circuit between the pad electrode PAD and the chip on film COF can be prevented.

Referring to FIG. 12, the rear view of the display device in accordance with an embodiment illustrates a state in which a first barrier layer BRL1, a pad electrode PAD, a second barrier layer BRL2, and a second base layer BSL2 are attached to a lower surface of a display panel DP in a state in which the display device shown in FIG. 2 is viewed in the third direction.

A base layer BSL (or a second base layer BSL2) may be a rigid or flexible substrate. For example, in case that the second base layer BSL2 is a rigid substrate, the second base layer BSL2 may be implemented as a glass substrate, a quartz substrate, a glass ceramic substrate, a crystalline glass substrate, or the like. In case that the second base layer BSL2 is a flexible substrate, the second base layer BSL2 may be implemented as a polymer organic substrate including polyimide, polyamide or the like, a plastic substrate, or the like.

The base layer BSL may include a gate pad part 100 and a data pad part 200. At least one pad electrode may be located in the gate pad part 100. At least one pad electrode may be located in the data pad part 200.

The gate pad part 100 may be disposed at a side of the base layer BSL. The gate pad part 100 may be electrically connected to the scan line Si and the control line CLi, which are shown in FIGS. 2 and 3. The gate pad part 100 may be electrically connected to fan-out lines (not shown) disposed in a fan-out area FAN.

Data pad parts 200 may be disposed at a side of the base layer BSL. The data pad part 200 may be electrically connected to the data line Dj and the sensing line SENj, which are shown in FIGS. 2 and 3. The data pad part 200 may be electrically connected to fan-out lines disposed in a fan-out area FAN.

The base layer BSL may include first openings OPN1. Each first opening OPN1 may surround the gate pad part 100 and surround the data pad part 200. For example, the gate pad part 100 may be disposed in the first opening OPN1, and the data pad part 200 may be disposed in the first opening OPN1. The first opening OPN1 of the base layer BSL may correspond to the first opening OPN1 shown in FIGS. 7 and 11.

Referring to FIG. 13, a first opening OPN1 and a chip on film COF of a base layer BSL of the display device in accordance with an embodiment are illustrated.

The first opening OPN1 may correspond to the first opening OPN1 shown in FIG. 12. Accordingly, the lower surface of the first barrier layer BRL1 and the lower surface of the pad electrode PAD, which are shown in FIGS. 7 to 11, are exposed in the first opening OPN1. First grooves GRO1 formed at the lower surface of the first barrier layer BRL1 are exposed in the first opening OPN1, and two second grooves GRO2 formed at the lower surface of the pad electrode PAD are exposed in the first opening OPN1.

A flexible film FF of the chip on film COF is located such that at least a portion of the flexible film FF overlaps the first opening OPN1. For example, the flexible film FF may be located to overlap a ½ area of the first opening OPN1.

A lead part LDP of the chip on film COF is located such that a portion of the lead part LDP overlaps the second groove GRO2. For example, the width of the lead part LDP of the chip on film COF may be smaller than that of the second groove GRO2. The lead part LDP may directly contact a lower surface (e.g., a second layer PADb) of the pad electrode PAD through the second layer GRO2.

A connection ball SB may be located such that at least a portion of the connection ball SB overlaps each of the flexible film FF, the lead part LDP, and the pad electrode PAD. For example, a ½ area of the connection ball SB may be located to overlap the flexible film FF and the lead part LDP. The connection ball SB may be located such that a majority of the connection ball SB overlaps the pad electrode PAD. Accordingly, the connection ball SB can electrically connect the pad electrode PAD and the chip on film COF to each other.

Since the connection ball SB is disposed in the second groove GRO2 formed at the lower surface of the pad electrode PAD, a spot at which the connection ball SB is disposed in the jet soldering process can be easily detected, and connection balls SB can be prevented from being arbitrarily distributed in the first groove GRO1 and the like.

Thus, the connection ball SB electrically connecting the pad electrode PAD and the chip on film COF is stably disposed, so that a short circuit between the pad electrode PAD and the chip on film COF can be prevented.

In accordance with the disclosure, a groove is formed at a lower surface of a pad electrode, and a connection ball for electrically connecting the pad electrode and a chip on film is stably disposed in the groove formed at the lower surface of the pad electrode, so that a short circuit of the display device can be prevented.

Further, a jet soldering process is used to electrically connect the pad electrode and the chip on film to each other, so that damage to the display panel can be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A display device comprising:
a first base layer including a first opening;
a first barrier layer located on a surface of the first base layer, and including a second opening; and
a pad electrode located on the first barrier layer and overlapping the second opening in a plan view, wherein
at least one first groove is formed at a surface of the first barrier layer,
a second groove is formed at a surface of the pad electrode, and the first opening exposes the at least one first groove and the second groove.

2. The display device of claim 1, wherein the pad electrode and a chip on film are electrically connected to each other through the first opening.

3. The display device of claim 2, wherein the pad electrode and the chip on film are electrically connected to each other through a connection ball.

4. The display device of claim 3, wherein the connection ball is located in the second groove formed in the pad electrode.

5. The display device of claim 1, wherein
the pad electrode includes a first layer and a second layer, the first layer includes titanium, and
the second layer includes copper.

6. The display device of claim 5, wherein the second groove is formed at a lower surface of the second layer.

7. The display device of claim 6, further comprising:
a second barrier layer overlapping an upper surface of the first barrier layer and an upper surface of the pad electrode in a plan view;
a second base layer located on the second barrier layer; and
a pixel circuit layer located on the second base layer, wherein the pixel circuit layer includes a data line.

8. The display device of claim 7, wherein
the second base layer includes an opening filled with a conductive material, and
the data line is electrically connected to the pad electrode through the conductive material.

9. A method of manufacturing a display device, the method comprising:
forming at least one metal part on a surface of a base layer;
forming a first barrier layer on the base layer and the at least one metal part;
forming a pad electrode on the first barrier layer;
forming a second barrier layer on the first barrier layer and the pad electrode; and
forming a first opening in the base layer, forming a first groove at a lower surface of the first barrier layer by removing the at least one metal part, and forming a second groove at a lower surface of the pad electrode by partially removing the pad electrode.

10. The method of claim 9, wherein the forming of the first groove and the forming of the second groove include using an atmospheric pressure plasma process to form the first and second grooves.

11. The method of claim 9, wherein the forming of the first barrier layer includes:
depositing the first barrier layer on the base layer and the at least one metal part; and
forming a second opening in the first barrier layer.

12. The method of claim 11, wherein the forming of the pad electrode includes:
depositing a pad electrode material on the first barrier layer, and
forming the pad electrode such that a portion of the pad electrode overlaps the second opening in a plan view.

13. The method of claim 12, wherein a second groove is formed at the lower surface of the pad electrode disposed in the second opening.

14. The method of claim 13, wherein a connection ball electrically connecting a chip on film and the pad electrode to each other is provided to correspond to the second groove.

15. A display device comprising:
at least one display panel, the at least one display panel including:
a first base layer including a first opening;
a first barrier layer located on a surface of the first base layer, the first barrier layer including a second opening; and
a pad electrode located on the first barrier layer and overlapping the second opening in a plan view, wherein
at least one first groove is formed at a surface of the first barrier layer,
a second groove is formed at a surface of the pad electrode, and
the first opening exposes the at least one first groove and the second groove.

16. The display device of claim 15, wherein in the first opening, the pad electrode and a chip on film are electrically connected to each other through a connection ball.

17. The display device of claim 15, wherein
the pad electrode includes a first layer and a second layer,
the first layer includes titanium, and
the second layer includes copper.

18. The display device of claim 17, wherein the second groove is formed at a lower surface of the second layer.

19. The display device of claim 18, further comprising:
a second barrier layer overlapping an upper surface of the first barrier layer and an upper surface of the pad electrode in a plan view;
a second base layer located on the second barrier layer; and
a pixel circuit layer located on the second base layer,
wherein the pixel circuit layer includes a data line.

20. The display device of claim 19, wherein
the second base layer includes an opening filled with a conductive material, and
the data line is electrically connected to the pad electrode through the conductive material.
